(19) United States
(12) Patent Application Publication
(10) Pub. No.: US 2007/0145359 A1
(43) Pub. Date: Jun. 28, 2007

(54) Materials for organic thin film transistors

(76) Inventor: Chi Ming Che, Hong Kong (HK)

Correspondence Address: COOPER & DUNHAM, LLP, 1185 AVENUE OF THE AMERICAS, NEW YORK, NY, 10036, US

(21) Appl. No.: 11/634,739

(22) Filed: Dec. 5, 2006

Related U.S. Application Data
(60) Provisional application No. 60/742,893, filed on Dec. 7, 2005.

(51) Int. Cl. H01L 29/08

(52) U.S. Cl. 257/40

(57) ABSTRACT

The invention provides organic thin film transistors including quinacridone derivatives with formula (I). These OTFTs are useful in making flat panel displays, photovoltaic devices and sensors. In the present invention, the disclosed quinacridone derivatives exhibit as p-type organic semiconductors in OTFTs.

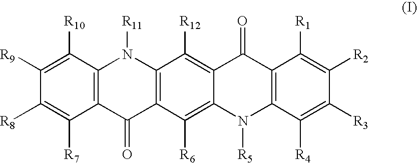

### CROSS-REFERENCE TO RELATED APPLICATION

This application claims the benefit of U.S. Patent Provisional Application No. 60/742,893 filed Dec. 7, 2005, the entire contents of which is incorporated herein by reference.

### FIELD OF THE INVENTION

The present invention relates to organic thin film transistors (OTFTs) that contain at least one quinacridone derivative as a charge-transporting material. Disclosed quinacridone derivatives exhibit hole-transporting properties in OTFTs. This invention further relates to quinacridone derivative-based OTFTs for applications in electronics including flat panel displays, photovoltaic devices, and sensors.

### REFERENCES

Several publications are referenced herein. Full citations for these publications are provided below. The disclosures of these publications are hereby incorporated herein by reference in their entirety.

### BACKGROUND OF THE INVENTION

Organic thin film transistors (OTFTs) have been used as alternatives to conventional silicon-based TFTs because of their low fabrication cost, high compatibility with glass and plastic substrates, large-area device coverage and simple fabrication process (see Horowitz, Adv.Mater., 10:365 (1998)). OTFTs can be used as flexible displays (see Sheraw et al., Appl. Phys. Lett., 80:1088 (2002)); sensors (see Bartic et al., Appl. Phys. Lett., 82:475 (2003)); and memory devices (see Chabinyc et al., Chem. Mater., 16:4509 (2004)). There are few stable, inexpensive organic semiconductors that have been found to be useful for OTFT applications.

Considerable progresses for OTFTs have been made, particularly focusing on the development of π-conjugated organic semiconductors (see Inoue et al., J. Appl. Phys., 95:5795 (2004); Sheraw et al., Adv. Mater., 15:2009 (2003); Yan et al., Adv. Mater., 17:1191 (2005)). π-Conjugated organic materials containing rigid and fused-ring structures are of interest where strong π-π interactions between the adjacent molecules could be achieved.

Investigations have been carried out in connection with p-type pentacene and its derivatives as organic semiconductors for OTFTs (see U.S. Pat. Nos. 6,284,562; 6,734,038 B2; 6,869,821 B2; Meng et al., J. Am. Chem. Soc., 127:2406 (2005); Anthony et al., J. Am. Chem. Soc., 127:4986 (2005)). Nonetheless, this class of materials is difficult to modify structurally due to its poor solubility in common organic solvents.

Oligothiophenes (see Katz et al., Chem. Mater., 7:2235 (1995)) and thiophene derivatives (see Yang et al., Adv. Funct. Mater., 15:671 (2005); Gamier et al., J. Am. Chem. Soc., 115:8716 (1993)) are another class of p-type organic semiconductors. It have been proven that the device performance increases by attaching long alkyl chains to the thiophene rings (see Katz et al., Chem. Mater, 10:633 (1998)). Arylacetylene-based p-type OTFTs have also been demonstrated (see Che et al., Adv. Mater., 17:1258 (2005)). Through the incorporation of electron-donor/-acceptor groups to π-conjugated arylacetylene oligomers, a charge carrier mobility of 0.3 cm²V⁻¹s⁻¹ and prolonged device stability were achieved.

Other p-type fused aromatic compounds such as dibenzothienobisbenzodithiophene (μ=0.2 cm²V⁻¹s⁻¹; /ₒₙ//_{off}=˜10⁶) (see Sirringhaus et al., J. Mater. Chem., 9:2095 (1999)), bisdithienothiophene (μ=0.05 cm²V⁻¹s⁻¹; /ₒₙ//_{off=10}⁸) (see Holmes et al., J. Am. Chem. Soc., 120:2206 (1998)), dihydrodiazapentacene (μ=0.006 cm²V⁻¹s⁻¹; /ₒₙ//_{off=5×10}³) (see Nuckolls et al., J. Am. Chem. Soc., 125:10284 (2003)) and diphenylbenzodichalcogenophenes (μ=0.17 cm²V⁻¹s⁻¹; /ₒₙ//_{off}=10⁵) (see Takimiya et al., J. Am. Chem. Soc., 126:5084 (2004)) have also been used for OTFTs.

The luminescent, light-sensitizing and structural properties of quinacridone and its derivatives have been widely studied (see Wightman et al., J. Am. Chem. Soc., 122:4972 (2000); Wang et al., J. Phys. Chem. B, 109:8008 (2005); Shi et al., Appl. Phys. Lett., 70:1665 (1997); Hiramoto et al., Jpn. J. Appl. Phys., 35:L349 (1996)), these compounds are stable in ambient environment and widely utilized as light-emitting and photoconductive materials.

### SUMMARY OF THE INVENTION

The present invention can provide organic thin film transistors (OTFTs) comprising one or more active layers, which employ at least one quinacridone derivatives as charge-transporting materials. The active charge-transporting material can conduct transport charges under applied bias. The transistors exhibit field effect mobility which is comparable to other organic thin film transistors. The present invention provides quinacridone derivative-based OTFTs for use in flat panel displays, photovoltaic devices and sensors.

The present invention can also provides organic thin film transistors (OTFTs), which employ an active layer comprising at least one quinacridone derivative as an active charge-transporting material. Preferably, the transistors can be operated as p-type OTFT.

In one embodiment of the present invention, an organic thin film transistor (OTFT) is provided and can comprise a gate electrode, an adhesive layer, a drain electrode, a source electrode, and an active layer comprising at least one quinacridone derivatives. In a preferred embodiment of the present invention, the quinacridone derivative can have the following formula: 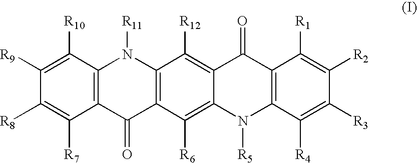
wherein each R¹-R¹² is independently —H, —OH, —NH₂, -halogen, —SH, —CN, —NO₂, —R¹³, —OR¹⁴, —SR¹⁴, —NHR¹⁴, or —N(R¹⁴)₂; each R¹³ is —(C₁-C₃₀)alkyl, -phenyl, -naphthyl or thiophene; each of which is unsubstituted or substituted with one or more —(C₁-C₁₅)alkyl, -phenyl, -naphthyl or -thiophene; R¹⁴ is defined as above for R¹³.

More preferably, the organic thin film transistors (OTFTs) employing quinacridone derivatives as illustrated in Formula (I) herein demonstrate a hole mobility of at least 0.1 cm²V⁻¹s⁻¹ and current on/off ratio of at least 10⁴ while voltage is applied.

The quinacridone derivatives-based OTFTs of the present invention can be applied to the fields of electronics, including flat panel displays, photovoltaic devices, sensors, and the like.

### BRIEF DESCRIPTION OF THE DRAWINGS

Further features and advantages of the invention can be understood by reviewing the following detailed description of the preferred embodiments taken together with attached drawings in which:

FIG. 1 shows a schematic diagram of field effect transistor including the quinacridone derivatives of the present invention;

FIG. 2 shows current-voltage (I-V) characteristics of OTFT fabricated with Q8 (channel length of 40 μm, channel width of 3000 μm) drain current (/_{DS}) versus drain voltage (V_{DS}) characteristic as a function of gate voltage (V_{G});

FIG. 3 shows current-voltage (I-V) characteristics of OTFTs fabricated with Q8 (channel length of 40 μm, channel width of 3000 μm): transfer curve in saturated regime at constant source-drain voltage of −40 V and square root of the absolute value of the current as a function of gate voltage;

FIG. 4 shows a scanning electron micrograph image of Q1 on silicon dioxide surface;

FIG. 5 shows a scanning electron micrograph image of Q2 on silicon dioxide surface;

FIG. 6 shows a scanning electron micrograph image of Q3 on silicon dioxide surface;

FIG. 7 shows a scanning electron micrograph image of Q6 on silicon dioxide surface; and

FIG. 8 shows a scanning electron micrograph image of Q8 on silicon dioxide surface.

### DETAILED DESCRIPTION OF THE PREFERRED EMBODIMENTS

The present invention can provide organic thin film transistors (OTFTs), which contain a quinacridone derivative or derivatives as an active charge-transporting material to facilitate charge flow in the transistors. In one embodiment, quinacridone derivatives can be used in an OTFT as illustrated in Formula I below, which can demonstrate a hole mobility of at least 0.1 cm²V⁻¹s⁻¹ and a current on/off ratio of at least 10⁴ respectively: 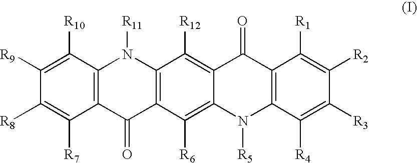
wherein each R¹-R¹² is independently —H, —OH, —NH₂, -halogen, —SH, —CN, —NO₂, —R¹³, —OR¹⁴, —SR¹⁴, —NHR¹⁴, or —N(R¹⁴)₂; each R¹³ is —(C₁-C₃₀)alkyl, -phenyl, -naphthyl or thiophene; each of which is unsubstituted or substituted with one or more —(C₁-C₁₅)alkyl, -phenyl, -naphthyl or -thiophene; R¹⁴ is defined as above for

Illustrative examples and exemplary compounds of formulae (I) are listed below in Table 1:

TABLE I

| | Com- |
|---|---|
| Structure | pound |
| 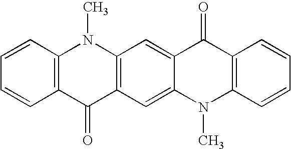 | Q1 |
| 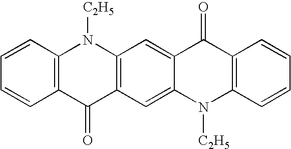 | Q2 |
| 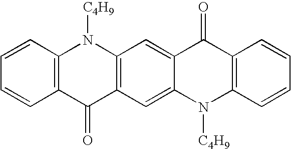 | Q3 |
| 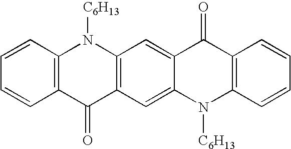 | Q4 |
| 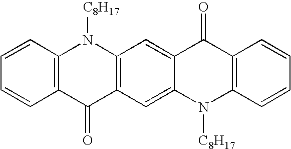 | Q5 |
| 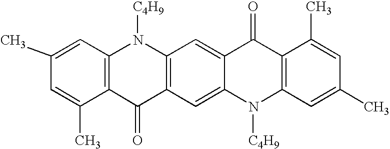 | Q6 |
| 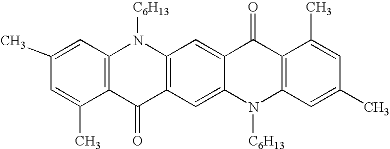 | Q7 |
| 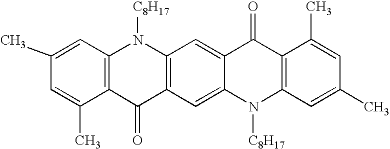 | Q8 |

The present invention can also provide an organic field effect transistor comprising a gate electrode, a metal oxide layer, an adhesive layer, a drain electrode, a source electrode, and an active layer comprising at least one quinacridone derivative as set forth above. The gate electrode can be silicon, doped silicon or aluminum. The metal oxide layer can be silicon oxide or aluminum oxide. The adhesive layer can be a layer of titanium or a layer of tungsten, or a layer of chromium. The drain electrode can be a layer of gold or a layer of platinum. The source electrode can be a layer of gold or a layer of platinum.

In one embodiment, the quinacridone derivative can be: 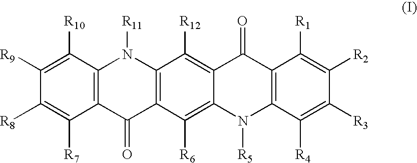
wherein each R¹-R¹² is independently —H, —OH, —NH₂, -halogen, —SH, —CN, —NO₂, —R¹³, —OR¹⁴, —SR¹⁴, NHR¹⁴, or —N(R¹⁴)₂; each R¹³ is —(C₁-C₃₀)alkyl, -phenyl, -naphthyl or thiophene; each of which is unsubstituted or substituted with one or more —(C₁-C₁₅)alkyl, -phenyl, -naphthyl or -thiophene; R¹⁴ is defined as above for R¹³.

In another embodiment, the quinacridone derivative can be a compound having the formula:

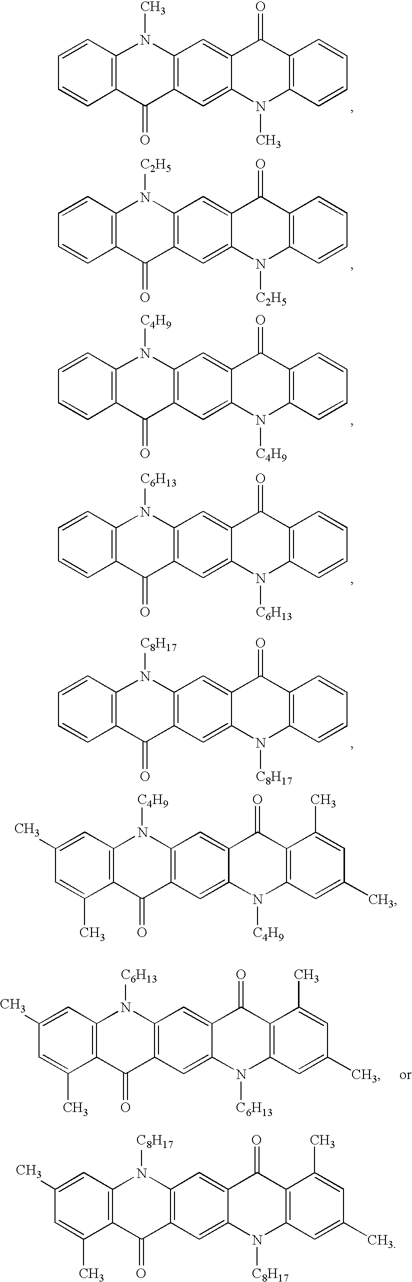

In a further embodiment, the quinacridone derivative contacts either the drain electrode or the source electrode. In another exemplary embodiment, the quinacridone derivatives act as a hole-transporting material to conduct a current flow under a bias. In one exemplary embodiment, the current flow is at least μA.

In the organic field effect transistor of the present invention, the field effect mobility is at least 0.1 cm²V⁻¹s⁻¹ and a current on/off ratio of at least 10⁴. The transistor comprising quinacridone derivatives can be potentially employed in a flat panel display, a photovoltaic device, a sensor, or the like.

The following examples are set forth to aid in understanding of the present invention but are not intended to, and should not be interpreted to limit in any way the present invention.

### EXAMPLE 1

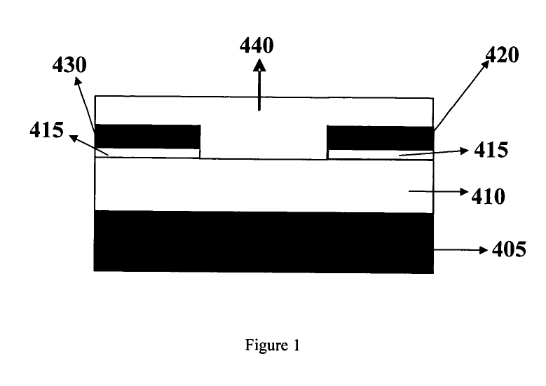

The configuration of quinacridone derivatives-based transistor of the present invention is schematically shown in FIG. 1. The transistor 400 has multiple layers as shown. Gate oxide 410 preferably comprising SiO₂ is deposited upon gate electrode 405, n-type Si gate. Thin adhesion layer 415 comprising Ti is placed on the top of layer 410. Gold drain electrode 420 and gold source electrode 430 are in contact with layer 415. An active layer 440 containing at least one quinacridone derivative is deposited on top of the layer 410, 420 and 430. The quinacridone derivative in layer 440 is in contact with drain electrode 420 and source electrode 430.

In a preferred embodiment, the thickness for the gate oxide 410 is 100 nm (permittivity=3.9) and the adhesion layer 415 is 10 nm. The active channel of transistor 400 is from 1 to 5 μm which is defined by distance between drain and source electrodes.

### EXAMPLE 2

Quinacridone derivative-based transistors can be fabricated on a substrate-gate structure. Gate oxide SiO₂ layer (100 nm, permittivity=3.9) was thermally grown on n-type Si substrates (the gate electrode). Image reversal photolithography was used to form an opening on the photoresist layer for the source and drain patterns. Source and drain metal layers (Au conductive film (50nm)) on a thin Ti adhesion film (10 nm) were deposited by vacuum deposition on top of the SiO₂ layer.

After the deposition of source and drain electrodes, standard lift-off processes in acetone solution was used to remove the unnecessary metal films on top of the photoresist pattern. The source/drain metal patterns on gate oxide substrate were cleaned with isopropyl alcohol and deionized water respectively, followed by drying under a nitrogen atmosphere. The profile of Au electrode was characterized with AFM that reveal smooth slope and regular patterns along the entire channel width. All the devices have a channel length and width of 40 and 3000 μm.

### EXAMPLE 3

In this example, the patterned transistor was cleaned before the deposition of active layer. The procedures are shown as follows: first, the transistor was washed with acetone, toluene, methanol and 18 MΩ water in sequence. Afterwards, the transistor was kept under a nitrogen atmosphere until dry and then transferred to a UV-ozone chamber. The transistor was cleaned under a UV ozone treatment for 15 min. and dried under a nitrogen atmosphere. Bottom contact OTFT devices comprising the quinacridone derivatives as active layers were fabricated respectively. All transistors were fabricated with quinacridone derivatives (thickness=50 nm; deposition rate=2 Å/s) on top of the patterned substrates under high vacuum conditions (1.0×10⁶ Torr) respectively.

### EXAMPLE 4

Thermal stabilities of Q1-Q8 were characterized by thermogravimetric analysis (TGA) before vacuum deposition. The decomposition temperature (T_{d}) was measured with a scanning rate of 15° C./min under a nitrogen atmosphere and the results are listed in Table 2. All quinacridone derivatives are thermally stable for vacuum thermal deposition with T_{d} up to 406° C. for 4.

TABLE 2
Thermal properties and field-effect characteristics of Q1-Q8.

| | TGA | | | |
|---|---|---|---|---|
| Compound | (° C.) | Mobility (cm²V⁻¹s⁻¹) | IₒₙI/_{off} | Threshold (V) |
| Q1 | 401 | 1.5 × 10⁻³ | 2 × 10² | −18 |
| Q2 | 375 | — | — | — |
| Q3 | 406 | — | — | — |
| Q4 | 393 | — | — | — |
| Q5 | 373 | — | — | — |
| Q6 | 375 | 1.5 × 10⁻³ | 1 × 10³ | −4 |
| Q7 | 376 | 3.1 × 10⁻³ | 1 × 10² | −12 |
| Q8 | 388 | 1.0 × 10⁻¹ | 1 × 10⁴ | −17 |

### EXAMPLE 5

The field-effect mobilities in saturation regime of OTFTs fabricated with Q1-Q8 were measured respectively and their performances are listed in Table 2. Q1-Q8 have a similar chemical structure; however, their transistor behaviors are significantly different. Only Q1 and Q6-8 show field effect mobilities in their corresponding OTFTs. Though Q2-Q5 have similar chemical structures to their Q6-8 counterparts and differ by having no methyl groups attached to quinacridone core, no transistor behavior was observed in these quinacridone derivative-based transistors.

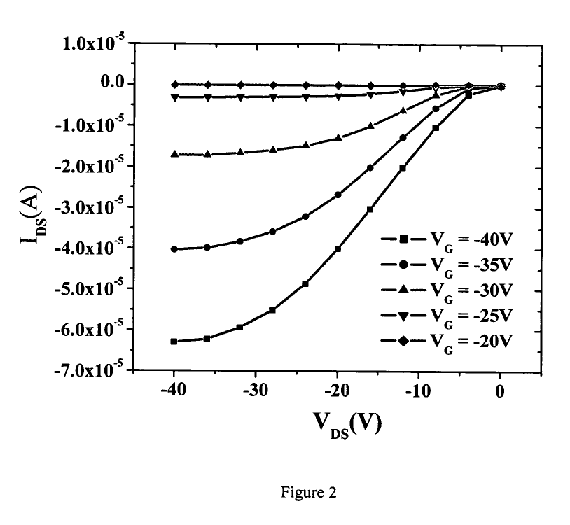

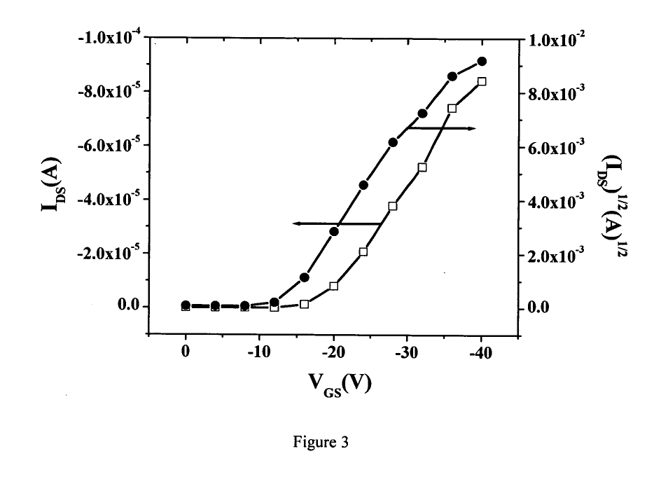

In this invention, N,N′-Di(n-octyl)-1,3,8,10-tetramethylquinacridone Q8 was found to exhibit the best field-effect mobility. FIGS. 2 and 3 show the output and transfer curves of an organic transistors fabricated with Q8. The device demonstrates typical p-type FET behavior in both saturated and linear regimes, which are comparable to the conventional transistor models. A field mobility and current on/off ratio (/ₒₙ//_{off}) as high as 1×10⁻¹ cm²V⁻¹s⁻¹ and ˜10⁴ was achieved.

Devices fabricated with N,N′-di(n-butyl)- or N,N′-di(n-hexyl)-1,3,8,10-tetramethylquinacridone Q6 and Q7 also exhibited field effect mobilities of 1.5 and 3.1×10⁻³ cm²V⁻¹s⁻¹. In comparison, a device fabricated with Q1 containing N,N′-dimethyl substituents on the quinacridone core showed a mobility of 1.5×10⁻³ cm²V⁻¹s⁻¹. The field-effect mobility of quinacridone-based OTFTs increases with increasing the side alkyl chain length of quinacridone moiety.

### EXAMPLE 6

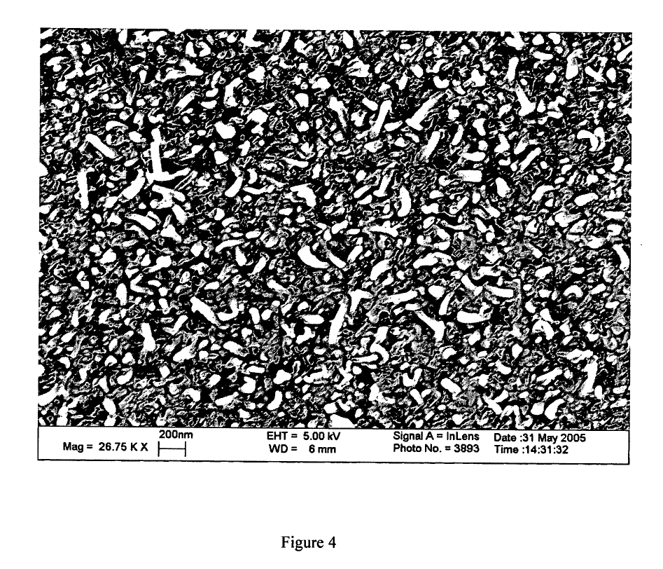

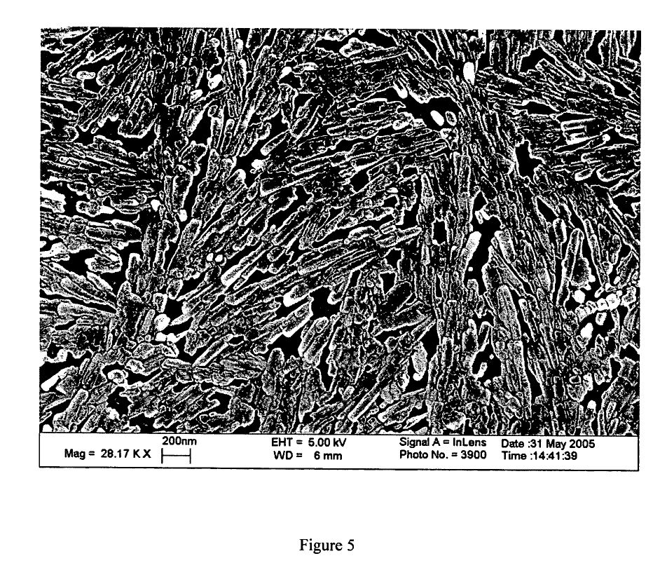

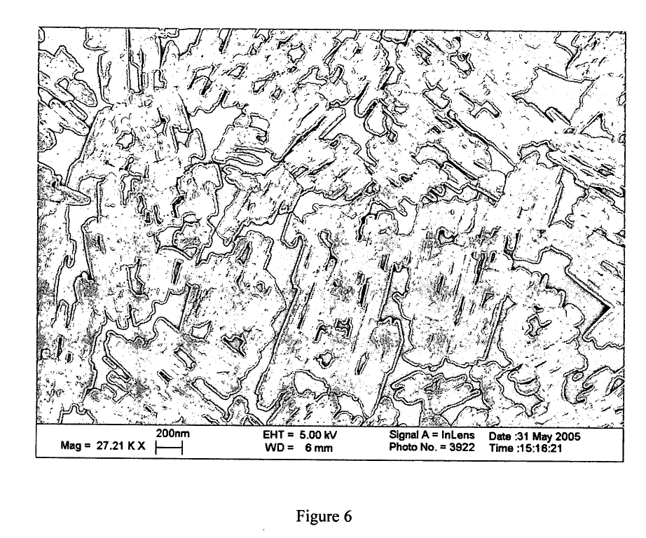

The film morphologies of Q1-Q3, Q6, and Q8 on silicon dioxide surface were characterized by SEM respectively under same condition. All films were deposited with a deposition rate of 2 Ås⁻¹. As shown in FIG. 4, Q1 exhibits a homogenous packing film with small crystal grains and the field effect mobility of Q1-based OTFT was 1.5×10⁻³ cm²V⁻¹s⁻¹. Q2 and Q3 which containing N,N′-diethyl and N,N′-di(n-butyl) side chains show large-gap and discontinuous flat crystals which separate far from each others (FIGS. 5 and 6). The loose-fitting flat crystals of Q2 and Q3 result in less π-π interaction between their contiguous molecules.

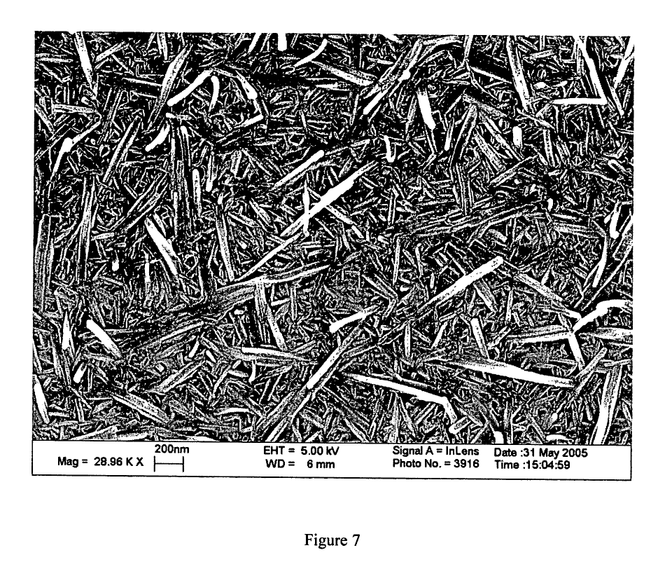

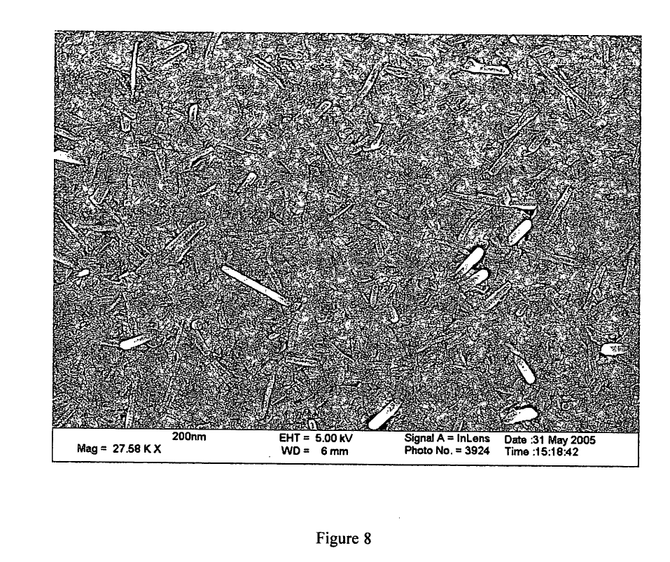

Compared to Q3, Q6 containing N,N′-di(n-butyl) groups plus four methyl substituents on the quinacridone core showed a field effect mobility of 1.5 ×10⁻³ cm²V¹⁻¹s⁻. This finding is supported by the SEM micrograph of Q6 film (FIG. 7) where polycrystalline grain structure was observed. By increasing the chain lengths from —C₄H₉ (Q6) to —C₈H₁₇ (Q8), the crystal packing structure transforms from loose (Q6, FIG. 7) to compact grains structure (Q8, FIG. 8). Evidently, a condensed crystal structure is far more preferable for charge carriers flow. Thus, the field effect mobility of Q6-based OTFT was 1.5×10⁻³ cm²V⁻¹s⁻¹ which was two orders of magnitude less than that reported for Q8 (Table 2).

These results reveal that the charge carrier mobility of quinacridone molecules is highly dependent on the film morphology, which in turn depends on the chemical structure of the molecules. The presence of four methyl substituents and long N,N′-di(n-octyl) side chains in Q8 induce formation of a dense and squashed crystal packing structure with polycrystalline grains. The mobility of Q8-based OTFT (10⁻¹ cm²V⁻¹s⁻¹) was about 100 times better than that of the other corresponding quinacridone derivatives (˜10⁻³ cm²V⁻¹s⁻¹).

The above description and examples are only illustrative of preferred embodiments which achieve the objects, features, and advantages of the present invention, and it is not intended that the present invention be limited thereto. Any modifications of the present invention which come within the spirit and scope of the following claims is considered part of the present invention.

### REFERENCES

The following references and other other patents, patent applications or other publications referred to in this application are incorporated by reference herein:

1. G. Horowitz, Organic field-effect transistors, Adv Mater. 1998, 10, 365-377.

2. C. D. Sheraw, L. Zhou, J. R. Huang, D. J. Gundlach, T. N. Jackson, M. G. Kane, I. G. Hill, M. S. Hammond, J. Campi, B. K. Greening J. Francl, J. West, Organic thin-film transistor-driven polymer-dispersed liquid crystal displays on flexible polymeric substrates, Appl. Phys. Lett. 2002, 80, 1088-1090.

3. C. Bartic, A. Campitelli, S. Borghs, Field-effect detection of chemical species with hybrid organic/inorganic transistors, Appl. Phys. Lett. 2003, 82, 475-477.

4. M. L. Chabinyc, A. Salleo, Materials requirements and fabrication of active matrix arrays of organic thin-film transistors for displays, Chem. Mater., 2004, 16, 4509-4521.

5. Y. Inoue, S. Tokito, Organic thin-film transistors based on anthracene oligomers, J. Appl Phys. 2004, 95, 5795-5799.

6. C. D. Sheraw, T. N. Jackson, D. L. Eaton, J. E. Anthony, Functionalized pentacene active layer organic thin-film transistors, Adv. Mater. 2003, 15, 2009-2011.

7. J. Zhang, H. Wang, X. Yan, J. Wang, J. Shi, D. Yan, Phthalocyanine Composites as high-mobility semiconductors for organic thin-film transistors, Adv. Mater. 2005, 17, 1191-1193.

8. B. J. Batlogg, C. Kloc, J. H. Scnon, Thin film transistors, U.S. Pat. No. 6,284,562.

9. M. Shtein, S. R. Forrest, Method of manufacturing high-mobility organic thin films using organic vapor phase deposition, U.S. Pat. No. 6,734,038 B2

10. D. P. Knipp, J. E. Northrup, R. A. Street, Method for producing organic electronic devices on deposited dielectric materials, U.S. Pat. No. 6,869,821 B2.

11. H. Meng, F. Sun, M. B. Goldfinger, G. D. Jaycox, Z. Li, W. J. Marshell, G. S. Blackman, High-performance, stable organic thin-film field-effect transistors based on bis-5′-alkylthiophen-2′-yl-2,6-anthracene semiconductors, J. Am. Chem. Soc. 2005, 127, 2406-2407.

12. M. M. Payne, S. R. Parkin, J. E. Anthony, C. C. Kuo, T. N. Jackson, Organic field-effect transistors from solution-deposited functionalized acenes with mobilites as high as 1 cm²V·s, J. Am. Chem. Soc. 2005, 127, 4986-4987.

13. H. E. Katz, L. Torsi, A. Dodabalapur, Synthesis, material properties, and transistor performance of highly pure thiophene oligomers, Chem. Mater. 1995, 7, 2235-2237.

14. H. Yang, T. J. Shin, L. Yang, K. Cho, C. Y. Ryu, Z. Bao, Effect of mesoscale crystalline structure on the field-effect mobility of regioregular poly(3-hexyl thiophene) in thin-film transistors, Adv. Funct. Mater. 2005, 15, 671-676.

15. F. Gamier, A. Yassar, R. Hajlaoui, G. Horowitz, F. Deloffre, B. Servet, S. Ries, P. Alnot, Molecular engineering of organic semiconductors: design of self-assembly properties in conjugated thiophene oligomers, J. Am. Chem. Soc. 1993, 115, 8716-8721.

16. H. E. Katz, J. G. Laquindanum, A. J. Lovinger, Synthesis, solubility, and field-effect mobility of elongated and oxa-substituted α, ω-Dialkyl thiophene oligomers. extension of “polar intermediate” synthetic strategy and solution deposition on transistor substrates, Chem. Mater. 1998, 10, 633-638.

17. V. A. L. Roy, Y. G. Zhi, Z. X. Xu, S. C. Yu, P. W. H. Chan, C. M. Che, Functionalized arylacetylene oligomers for organic thin-film transistors (OTFTs). Adv. Mater. 2005, 17, 1258-1261.

18. H. Sirringhaus, R. H. Friend, C. Wang, J. Leuninger, K. Mullen, Dibenzothienobisbenzothiophene—a novel fused-ring oligomer with high field-effect mobility, J. Mater. Chem. 1999, 9, 2095-2101.

19. X. C. Li, H. Sirringhaus, F. Garnier, A. B. Holmes, S. C. Moratti, N. Feeder, W. Clegg, S. J. Teat, R. H. Friend, A highly π-stacked organic semiconductor for thin film transistors based on fused thiophenes, J. Am. Chem. Soc. 1998, 120, 2206-2207.

20. Q. Miao, T. Q. Nguyen, T. Someya, G. B. Blanchet, and C. Nuckolls, Synthesis, assembly, and thin film transistors of dihydrodiazapentacene: an isostructural motif for pentacene. J. Am. Chem. Soc. 2003, 125, 10284-10278.

21. K. Takimiya, Y. Kunugi, Y. Konda, N. Niihara, T. Otsubo, 2,6-Diphenylbenzo[1,2-b:4,5-b′]dichalcogenophenes: a new class of high-performance semiconductors for organic field-effect transistors, J. Am. Chem. Soc. 2004, 126, 5084-5085.

22. E. M. Gross, J. D. Anderson, A. F. Slaterbeck, S. Thayumanavan, S. Barlow, Y. Zhang, S. R. Marder, H. K. Hall, M. Flore Nabor, J. F. Wang, E. A. Mash, N. R. Armstrong, R. M. Wightman, Electrogenerated chemiluninescence from derivatives of aluminum quinolate and quinacridones: cross-reactions with triarylamines lead to singlet emission through triplet-triplet annihilation pathways, J. Am. Chem. Soc. 2000, 122, 4972-4979.

23. K. Ye, J. Wang, H. Sun, Y. Liu, Z. Mu, F. Li, S. Jiang, J. Zhang, H. Zhang, Y. Wang ,C. M. Che, Supramolecular structures and sssembly and luminescent of quinacridone derivatives, J. Phys. Chem. B 2005, 109, 8008-8016.

24. J. Shi, C. W. Tang, Doped organic electroluminescent devices with improved stability, Appl. Phys. Lett. 1997, 70, 1665-1667.

25. M. Hiramoto, S. Kawase, M. Yokohama, Photoinduced hole injection multiplication in p-type quinacridone pigment films, Jpn. J. Appl. Phys. 1996, 35, L349-L351.

What is claimed is:

1. An organic field effect transistor, comprising: a gate electrode; a metal oxide layer; an adhesive layer; a drain electrode; a source electrode, and an active layer comprising at least one quinacridone derivatives.

2. The transistor of claim 1, wherein the gate electrode is silicon, doped silicon or aluminum.

3. The transistor of claim 1, wherein the metal oxide layer is silicon oxide or aluminum oxide.

4. The transistor of claim 1, wherein the adhesive layer is a layer of titanium or a layer of tungsten, or a layer of chromium.

5. The transistor of claim 1, wherein the drain electrode is a layer of gold or a layer of platinum.

6. The transistor of claim 1, wherein the said source electrode comprising is a layer of gold or a layer of platinum.

7. The transistor of claim 1, wherein the quinacridone derivative is: 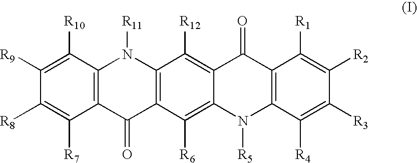
each R¹-R¹² is independently —H, —OH, —NH₂, -halogen, —SH, —CN, —NO₂, —R¹³, —OR¹⁴, —SR¹⁴, —NHR¹⁴, or —N(R¹⁴)₂; each R¹³ is —(C₁-C₃₀)alkyl, -phenyl, -naphthyl or thiophene; each of which is unsubstituted or substituted with one or more —(C₁-C₁₅)alkyl, -phenyl, -naphthyl or -thiophene; R¹⁴ is defined as above for R¹³.

8. The transistor of claim 7, wherein the quinacridone derivative is a composition having the following structure:

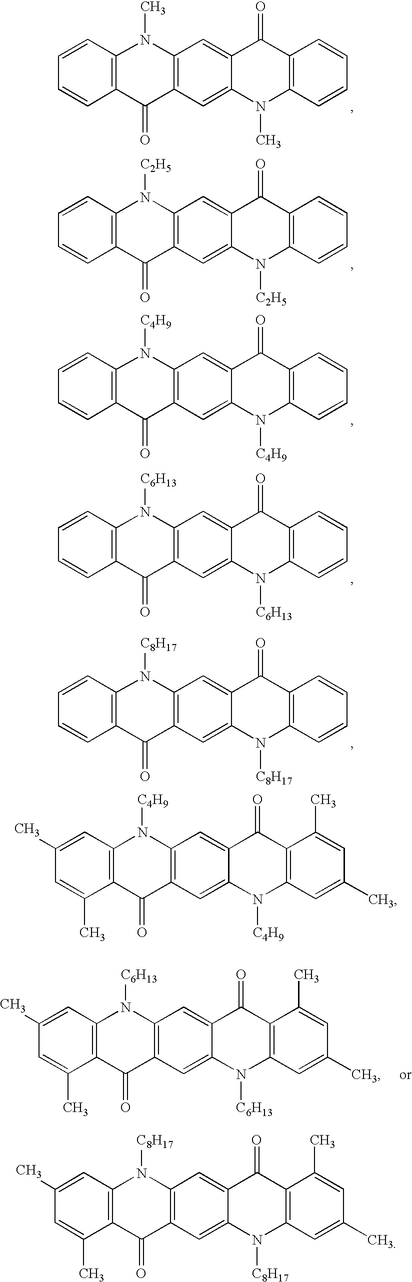

11. The transistor of claim 7, wherein the quinacridone derivative contacts either the drain electrode or the source electrode.

12. The transistor of claim 7, wherein the quinacridone derivative acts as a hole-transporting material to conduct a current flow under a bias.

13. The transistor of claim 7, wherein the current flow is at least in μA.

14. The transistor of claim 7, wherein the field effect mobility is at least 0.1 cm²V⁻¹s⁻¹ and a current on/off ratio of at least 10⁴.

15. The transistor of claim 7, wherein the transistor is in a flat panel display, a photovoltaic device or a sensor.

16. A method for mailing an organic field effect transistor comprising: providing a gate oxide on a gate electrode; providing a thin adhesion layer on top of the gate electrode and a drain electrode and a source electrode in contract with the adhesion layer; and providing a layer of a quinacridone derivative in contact with the drain electrode and the source electrode.

17. A method according to claim 16 wherein the drain and source electrodes are gold or platinum.

18. A method according to claim 16, wherein the quinacridone derivative is 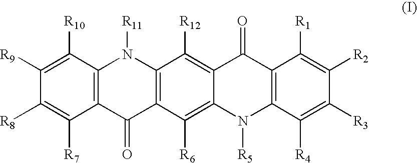
each R¹-R¹² is independently —H, —OH, —NH₂, -halogen, —SH, —CN, —NO₂, —R¹³, —OR¹⁴, —SR¹⁴, —NHR¹⁴, or —N(R¹⁴)₂; each R¹³ is —(C₁-C₃₀)alkyl, -phenyl, -naphthyl or thiophene; each of which is unsubstituted or substituted with one or more —(C₁-C₁₅)alkyl, -phenyl, -naphthyl or -thiophene; R¹⁴ is defined as above for R¹³.

19. A method according to claim 19 wherein the quinacridone derivative has the following structure:

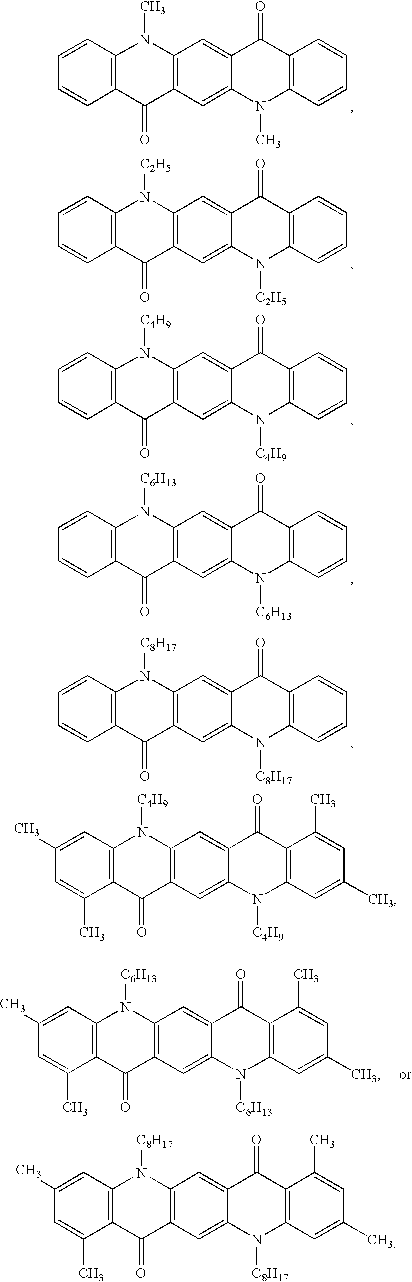

20. A flat panel display comprising at least one OTFT according to claim 7.

21. A photovoltaic device comprising at least one OTFT according to claim 7.
